(19) United States
(12) Patent Application Publication
(10) Pub. No.: US 2016/0239036 A1
(43) Pub. Date: Aug. 18, 2016

(54) DUAL SUPPLY

(71) Applicant: Intel Corporation, Santa Clara, CA (US)

(72) Inventors: Fabrice Paillet, Hillsboro, OR (US); Gerhard Schrom, Hillsboro, OR (US); Anant Deval, Portland, OR (US); Rajan Vijayaraghavan, Hillsboro, OR (US)

(21) Appl. No.: 14/621,261

(22) Filed: Feb. 12, 2015

(51) Int. Cl. G05F 3/08; G06F 1/26; H02M 1/08; H03K 3/011; H02M 3/158

(52) U.S. Cl. CPC G05F 3/08; H03K 3/011; H02M 3/158; H02M 1/08; G06F 1/266; G06F 1/263; H02M 2001/0045

(57) ABSTRACT

The present disclosure provides a power delivery scheme to provide a parallel regulation feature for integrated voltage regulators (IVRs).

### TECHNICAL FIELD

The present invention relates generally to power supplies and in particular, to power supply solutions for on-chip voltage domains.

### BRIEF DESCRIPTION OF THE DRAWINGS

Embodiments of the invention are illustrated by way of example, and not by way of limitation, in the figures of the accompanying drawings in which like reference numerals refer to similar elements.

FIG. 1A is a diagram of a computing device with a processor having multiple parallel LVR/IVR voltage supplied domains in accordance with some embodiments.

FIG. 1B is a schematic of an IVR portion from a single voltage domain from the computing device of FIG. 1A in accordance with some embodiments.

FIG. 2 is a block diagram of circuitry for a single representative FIVR in accordance with some embodiments.

FIG. 3 is a diagram showing a single FIVR/LVR block for supplying power to a voltage domain in accordance with some embodiments.

FIG. 4 is a diagram showing a routine 401 for transitioning from the FIVR to the LVR in accordance with some embodiments.

FIG. 5 is a diagram showing a routine for transitioning from an LVR to a FIVR for a domain power supply in accordance with some embodiments.

### DETAILED DESCRIPTION

The present disclosure provides a power delivery scheme to provide a parallel regulation feature for integrated voltage regulators (IVRs). For a supply domain, this feature may provide seamless transfer of voltage regulation and power delivery from the IVR to an alternate, more efficient, parallel (linear) regulator (LVR) during specific (light) load conditions where overall IVR power efficiency may be low. When Parallel regulation is activated the IVR can be fully powered down and its input supply lowered, if not turned off, reducing or removing altogether sources of static leakage or active power on the IVR input supply rail. The parallel regulator can be a linear voltage regulator (LVR) or potentially another kind of efficient regulator for the specific operating condition of interest, like a switched capacitor regulator or a smaller switching mode voltage regulator.

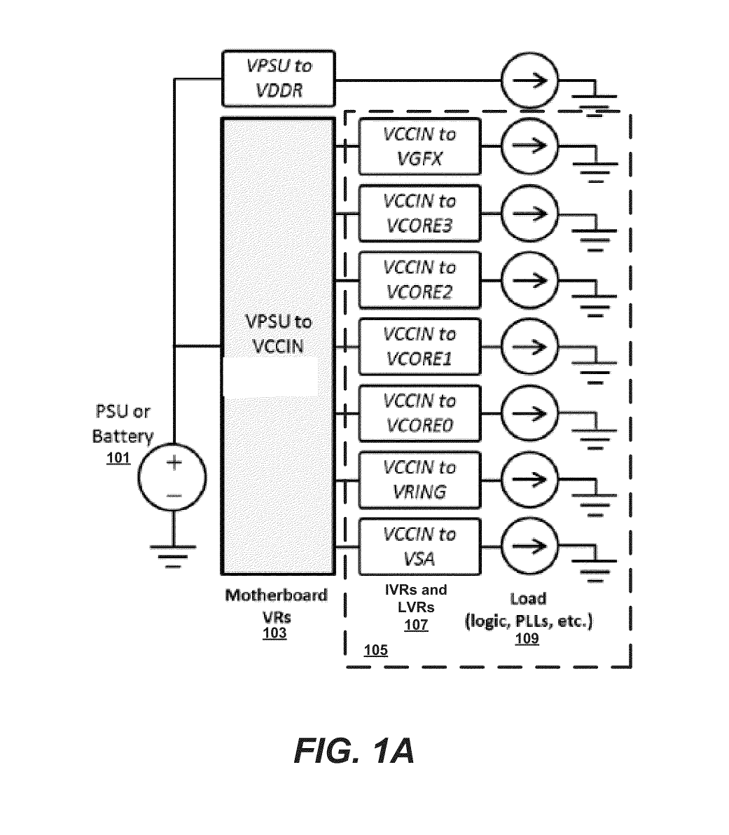

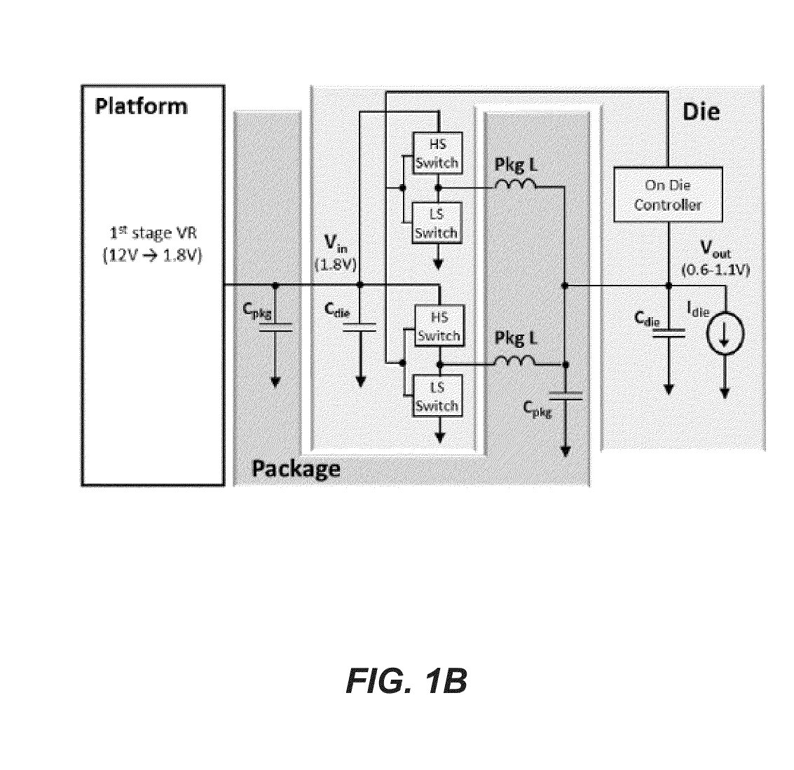

FIG. 1A is a diagram showing power domains for an exemplary computing device in accordance with some embodiments. It includes a processor 105 that is powered from a power source 101 (PSU or battery) through off-chip regulators 103. The processor 105 has separate IVR/LVR voltage domains 107 for powering various different loads 109. The processor 105 could correspond to any suitable processor (e.g., high-end server chip, SoC, etc.). For example, it could be implemented with an Intel® 4th generation Core™ microprocessor.

A first stage VR (from 103), which is on a motherboard, converts from the PSU (power supply unit) or battery voltage (e.g., 12V to 20V) to a lower voltage (e.g., 1.8 V for active modes and 1.3 for reduced power modes). These supplies are distributed through input supply rails across the microprocessor die. The IVR/LVR blocks function as a second conversion stage. For example, there could be between 8 and 31 IVR/LVR domains depending on processor configuration. In some embodiments, the IVRs are implemented with FIVRs (fully integrated voltage regulators). Each IVR is independently programmable to achieve optimal operation given the requirements of the domain it is powering. The settings may be optimized by a power control unit (PCU), which may specify the input voltage, output voltage, number of operating phases, and a variety of other settings to minimize the total power consumption of the die.

It should be appreciated that IVR (integrated voltage regulator) may comprise any suitable switching type regulator with at least its PWM (pulse width modulation) circuitry integrated into the chip for which it is supplying power. A FIVR (fully integrated voltage regulator) is a type of IVR. A FIVR may be implemented with any suitable switching DC regulator technology. It will typically have most, if not all, of its components housed in a semiconductor package (package including one or more dies) for which it is supplying regulated power. For example, in some embodiments, the power FETs, control circuitry and high frequency decoupling components might be on the die, while the inductors and mid-frequency input decoupling capacitors might be in the package.

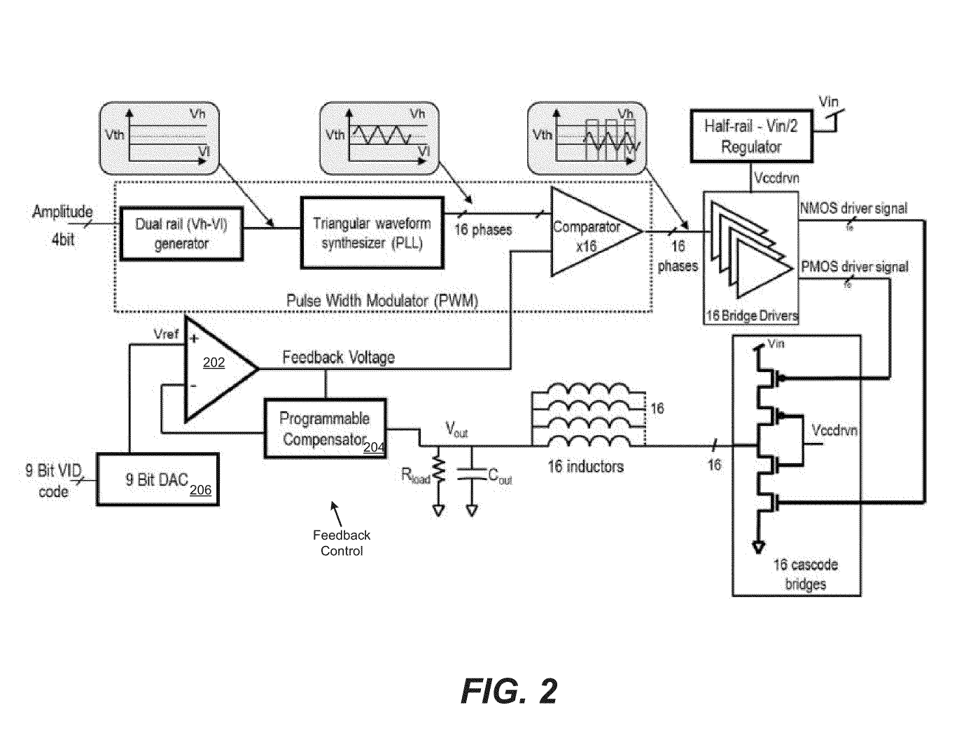

A block diagram representing the circuitry for a single FIVR domain is shown in FIG. 2. This FIVR is a 140 MHz synchronous multiphase buck converter with 16 phases. In some embodiments, the buck regulator bridges may be formed by replacing power gates from previous designs with NMOS and PMOS cascode power switches. The cascode configuration allows the power switches to be implemented with logic devices from more advanced (e.g., smaller feature size) semiconductor processes, and at the same time, they may be able to handle reasonably high input voltages (e.g., up to 1.8 VDC). This can reduce the cost of extra processing steps for high voltage devices, while achieving desired switching characteristics.

The bridge drivers may be controlled thru high-voltage level-shifters and may support ZVS (zero-voltage switching) and ZCS (zero-current-switching) soft-switching operation. The gates of the cascode devices are coupled to a “half-rail” supply (e.g., Vccdrvn) regulated to Vin/2. This may also be used as a low-side supply for the PMOS bridge driver as well as for the high-side supply of the NMOS bridge driver. The area occupied by the power switches and drivers is small, so they may be efficiently distributed across the die, for example, above a connection to their associated package inductor, which minimizes routing losses. The driver circuitry is interleaved with the power switches in an array which can minimize parasitics to allow for very high switching frequencies. This also can allow the size of the bridge to be scaled based on the current requirements and optimization points for each supply domain.

In the depicted embodiment, Each FIVR domain is controlled by a FIVR Control Module (FCM). The FCM (not expressly shown) contains the circuitry for generating the PWM signals using double-edge modulation, as indicated in FIG. 2 by the dashed box. Separate circuitry (also not shown) manages phase current balancing, and the resulting digital PWM signals are distributed from the FCM to individual bridges. The PWM frequency, PWM gain, phase activation, and the angle of each phase may be programmable in fine increments to enable optimal efficiency and minimum voltage ripple across a span of different operating points. In addition, spread-spectrum may be used for EMI and RFI (Radio Frequency Interference) control.

As is shown in FIG. 2, included (e.g., as part of the FCM module) is compensator circuitry (feedback control circuitry). The FIVR compensator closes the voltage regulation loop. It is called a compensator because of the combination of passive devices (e.g., in programmable compensation block 204) added around it to compensate the loop to insure stable closed loop operation. Due to the phase shift introduced in the system by the inductor (LC) output filter, the closed loop operation would likely not be stable without proper compensation (through an RC network which is part of programmable compensator 204). The compensator output (labeled “Feedback Voltage”) drives the PWM (Pulse Width Modulator), and it sets the duty cycle of the converter to maintain proper output voltage.

A high-precision 9-bit DAC 206 generates a reference voltage for a programmable, high bandwidth analog fully differential type-3 compensator (formed from amplifier 202 and programmable RC compensation circuit 204). Sense lines feed the FIVR output voltage back to the compensator. The compensator may be programmed individually for each voltage domain based on its output filter, and can be reprogrammed while the domain is active to maintain optimal transient response, e.g., as phase shedding occurs. Pertinent to this disclosure, it may also be used for transitioning back to a FIVR mode from an LVR mode. The compensator output voltage (Feedback Voltage) is measured before the FIVR is deactivated. Then, when the FIVR is to be re-activated (transition from LVR to FIVR), the amplifier 202 is disable (e.g., tri-stated output), and a separate DAC (not shown) is used to generate a priming voltage at the compensator output (output of 202) to precharge the output at the stored level from when the FIVR was de-activated. In this way, the PWM is started at a value that should generate a FIVR output voltage equivalent to what it was before being deactivated.

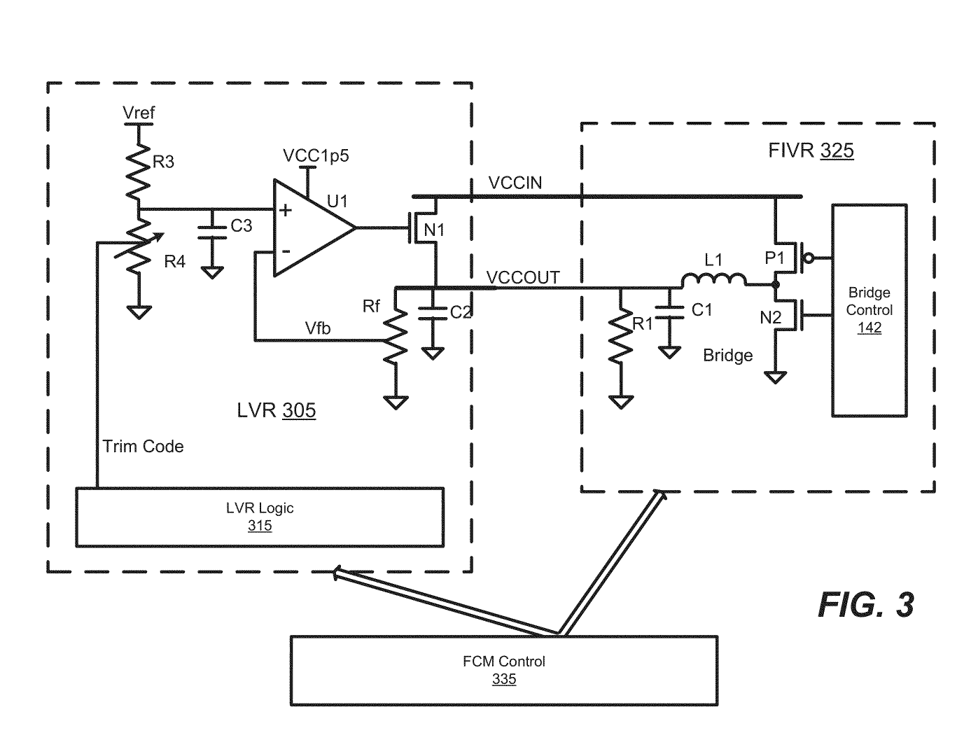

FIG. 3 is a diagram showing a single FIVR/LVR block for supplying power to a voltage domain in accordance with some embodiments. The block includes an LVR 305 coupled in parallel with the FIVR 325 to provide power to the output rail (VCCOUT) when the input supply (VCCIN) is at a reduced level. VCCIN is the primary input power supply for both FIVR and Parallel LVR. The VCCIN rail can likely not be fully turned off but leakage power can be reduced drastically by reducing the VCCIN voltage, e.g., from between 1.6 V and 1.8 V to a voltage between 1.2 V and 1.3 V. The FIVR and LVR outputs are physically shorted (as shown in the figure) for the VCCOUT rail (although their output stages, either through switches or direct deactivation, may be disengaged from the output VCCOUT).

In some embodiments, when the processor is to be in an active state (e.g., ACPI C0-C3), VCCIN will go to an active level (e.g., 1.8 V). In this higher (active) input supply mode, the FIVR is controlled to be active to regulate the output rail(s) VCCOUT, with the LVR deactivated. Alternately, during processor low power states (e.g., C7 and higher), the processor load reduces, and thus, in order to save power, VCCIN may be lowered, e.g., to 1.3 V. The LVR is activated to regulate the VCCOUT rail, while the FIVR is turned off. In some embodiments, procedures for transitioning between these regulators with very little (if any) voltage change is presented below. (The output voltage will remain substantially the same except that FIVR output ripple noise will disappear when the LVR is driving the output.)

In the depicted embodiment, a linear voltage regulator is used for LVR 305, and a FIVR is used for an IVR. An FCM control logic 335 (which may correspond to the FCM discussed with respect to the FIVR in FIG. 2) is configured to control operation and/or activation of the LVR and IVR. When the LVR is to be active, the FCM can control (or adjust) the LVR output through control of the LVR trim control logic 315. Among other things, the FCM may also monitor, store, and control compensator values for the FIVR, e.g., as described with respect to FIG. 2.

The parallel LVR 305 is designed to deliver a smaller amount of current than can the FIVR (but enough for a low power state condition) at a greater efficiency. It should be appreciated that while a simple linear regulator is shown for use as the low voltage regulator, any suitable regulator design could be employed. For example, alternate LVRs could be implemented with a small switching mode voltage regulator or a switched capacitor voltage converter. Ideally, the LVR will provide a suitably controllable output voltage, not be too complicated so as to incur excessive overhead, and importantly, operate with increased efficiency, as compared with the FIVR, at reduced input voltages.)

It should be appreciated that not all of the supply domains may have parallel LVRs as disclosed herein. For example, in some embodiments, parallel LVRs may not be used in some domains where full power is to be available during low power modes. Such domains could include, for example, platform controller rails that may be the only IVR rails active in low power state C7 while other rails (e.g., CPU core, graphics and LLC) are off. In some schemes, the parallel LVRs will be engaged in C7+ low power states where the power consumption of the CPU is low while the IVRs are used to supply those rails the rest of the time.

In operation, transition into the parallel LVR mode may be substantially transparent and seamless. The voltage remains the same, and the load being powered is unaware of the change in power delivery source. During regular FIVR operation (e.g., VCCIN being from 1.6V to 1.8V), the FIVR regulates the output power rail VCCOUT. During low power states (e.g., VCCIN reduced to between 1.2V and 1.3V), the FIVR is turned off and the parallel LVR is used to regulate the corresponding output power rail instead of the FIVR.

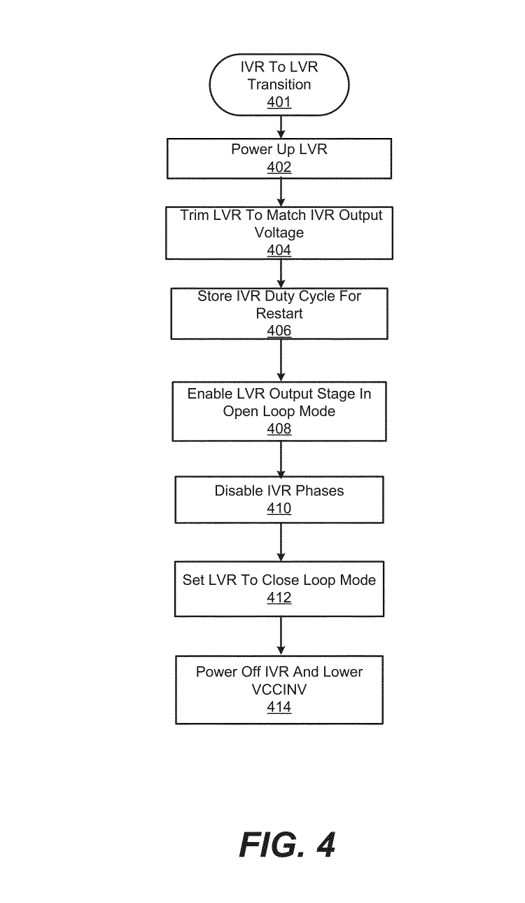

FIG. 4 is a diagram showing a routine 401 for transitioning from the FIVR to the LVR to regulate the output rail (VCCOUT). At 402, the LVR is powered up. Next, at 404 (while the FIVR is still operational), the LVR is trimmed to match the FIVR output voltage. This may be done in any suitable manner. For example, the input reference could be compared against the VCCOUT output until it is sufficiently equal, and this trim setting could then be used, especially in cases where the LVR output offset, relative to the reference voltage, is sufficiently small. In other cases, the LVR output could be compared against the FIVR output (VCCOUT), while the LVR output is decoupled from the VCCOUT rail. The LVR could then be trimmed until its output was matched with the FIVR output.

At 406, the FIVR duty cycle is stored (e.g., by the FCM). This will allow it to be used later for restart with the same duty cycle for the LVR to FIVR transition. Next, at 408, the LVR output stage is enabled to drive the output (VCCOUT) in open loop mode. Next, at 410, the FIVR phases are shut down, as the FIVR is deactivated. At 412, the LVR is then set for close loop operation. At this point, the LVR is driving the output rail. At 414, the FIVR may be powered off, and the VCCIN voltage is lowered to the lower level (e.g., 1.3 V).

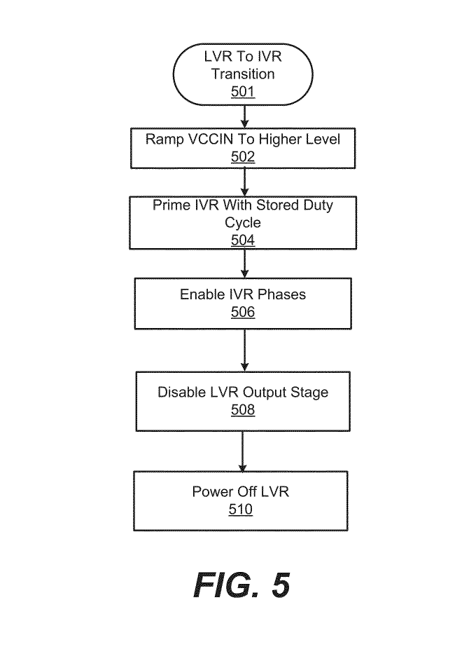

FIG. 5 is a diagram showing a routine 501 for transitioning from the LVR to the FIVR, e.g., when the VCCIN supply is to go to a higher active voltage level. At 502, VCCIN is ramped to 1.8V. Next, at 504, the FIVR is primed with the duty cycle settings stored from previous operation. Priming the compensator output with the recorded voltage level needed for the PWM to generate the same duty cycle as was present before the FIVR hand off the regulation to the LVR allows the FIVR to restart generating a voltage at substantially the same (if not identical) level as what it generated before being deactivated. (Note, if this is not done, the FIVR would likely ramp its output voltage from zero and initially short the LVR to ground.

At 506, the IVR phases are enabled. During this time, both the IVR and LVR will drive the output for a short time. Next, at 508, the LVR output stage is disabled. Finally, at 510, the LVR is powered off.

In the preceding description and following claims, the following terms should be construed as follows: The terms “coupled” and “connected,” along with their derivatives, may be used. It should be understood that these terms are not intended as synonyms for each other. Rather, in particular embodiments, “connected” is used to indicate that two or more elements are in direct physical or electrical contact with each other. “Coupled” is used to indicate that two or more elements co-operate or interact with each other, but they may or may not be in direct physical or electrical contact.

The term “PMOS transistor” refers to a P-type metal oxide semiconductor field effect transistor. Likewise, “NMOS transistor” refers to an N-type metal oxide semiconductor field effect transistor. It should be appreciated that whenever the terms: “MOS transistor”, “NMOS transistor”, or “PMOS transistor” are used, unless otherwise expressly indicated or dictated by the nature of their use, they are being used in an exemplary manner. They encompass the different varieties of MOS devices including devices with different VTs, material types, insulator thicknesses, gate(s) configurations, to mention just a few. Moreover, unless specifically referred to as MOS or the like, the term transistor can include other suitable transistor types, e.g., junction-field-effect transistors, bipolar-junction transistors, metal semiconductor FETs, and various types of three dimensional transistors, MOS or otherwise, known today or not yet developed.

The invention is not limited to the embodiments described, but can be practiced with modification and alteration within the spirit and scope of the appended claims. For example, it should be appreciated that the present invention is applicable for use with all types of semiconductor integrated circuit (“IC”) chips. Examples of these IC chips include but are not limited to processors, controllers, chip set components, programmable logic arrays (PLA), memory chips, network chips, and the like.

It should also be appreciated that in some of the drawings, signal conductor lines are represented with lines. Some may be thicker, to indicate more constituent signal paths, have a number label, to indicate a number of constituent signal paths, and/or have arrows at one or more ends, to indicate primary information flow direction. This, however, should not be construed in a limiting manner. Rather, such added detail may be used in connection with one or more exemplary embodiments to facilitate easier understanding of a circuit. Any represented signal lines, whether or not having additional information, may actually comprise one or more signals that may travel in multiple directions and may be implemented with any suitable type of signal scheme, e.g., digital or analog lines implemented with differential pairs, optical fiber lines, and/or single-ended lines.

It should be appreciated that example sizes/models/values/ranges may have been given, although the present invention is not limited to the same. As manufacturing techniques (e.g., photolithography) mature over time, it is expected that devices of smaller size could be manufactured. In addition, well known power/ground connections to IC chips and other components may or may not be shown within the FIGS, for simplicity of illustration and discussion, and so as not to obscure the invention. Further, arrangements may be shown in block diagram form in order to avoid obscuring the invention, and also in view of the fact that specifics with respect to implementation of such block diagram arrangements are highly dependent upon the platform within which the present invention is to be implemented, i.e., such specifics should be well within purview of one skilled in the art. Where specific details (e.g., circuits) are set forth in order to describe example embodiments of the invention, it should be apparent to one skilled in the art that the invention can be practiced without, or with variation of, these specific details. The description is thus to be regarded as illustrative instead of limiting.

What is claimed is:

1. A chip, comprising:
an input rail to receive an external DC supply voltage at a first level for a first mode and at a second level for a second mode, the second level being smaller than the first level;
an integrated switching-type voltage regulator (IVR) having an input coupled to the input rail and an output coupled to an output rail to provide a regulated DC voltage; and
a lower voltage regulator (LVR) having an input coupled to the input rail and an output coupled to the output rail to provide the regulated DC voltage in place of the IVR when the external DC supply is in the second mode.

2. The chip of claim 1, in which the LVR is a linear voltage regulator.

3. The chip of claim 1, in which the LVR is a switching type regulator.

4. The chip of claim 1, in which the IVR is a fully integrated voltage regulator (FIVR).

5. The chip of claim 1, comprising logic to transition from the IVR to the LVR when the external DC supply is to go into the second mode.

6. The chip of claim 5, in which the logic is part of a control module that controls duty cycle for the IVR.

7. The chip of claim 5, in which the logic, while the LVR is disengaged from the output rail, is to trim the LVR so that its output voltage will match that of the IVR, in controlling transition to the LVR.

8. A computing device, comprising:
a processor; and
a DC supply external to the processor to provide an input supply voltage;
the processor having multiple voltage domains, an IVR, and a parallel LVR powered from the input supply voltage, wherein at least one domain is to be powered by one of the IVR and parallel LVR depending on the level of the input supply voltage.

9. The computing device of claim 8, in which the processor is part of a server computer.

10. The computing device of claim 8, in which the LVR and IVR have outputs controllably coupled to a common output rail.

11. The computing device of claim 8, in which the IVR is a FIVR.

12. The computing device of claim 11, in which the FIVR has a circuit for starting a PWM at a desired level when the FIVR is activated.

13. The computing device of claim 12, in which the circuit for starting a PWM at a desired level includes a DAC to generate a voltage at a compensator output.
